(19) United States
(12) Patent Application Publication
(10) Pub. No.: US 2010/0038120 A1
(43) Pub. Date: Feb. 18, 2010

(54) Layered ceramic electronic component and manufacturing method therefor

(75) Inventors: Tatsuya Kojima, Tokyo (JP); Osamu Hirose, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/461,372

(22) Filed: Aug. 10, 2009

(30) Foreign Application Priority Data
Aug. 13, 2008 (JP) 2008-208459
Aug. 13, 2008 (JP) 2008-208498

(51) Int. Cl. H05K 1/09; H05K 1/11; C03B 29/00

(52) U.S. Cl. 174/257; 174/266; 156/89.12

(57) ABSTRACT

Provided is a manufacturing method of a layered ceramic electronic component capable of preventing appearance of a gap between a dielectric layer and a via electrode to achieve reliable conduction between the via electrode and an internal electrode and at the same time, capable of effectively preventing occurrence of structural defects in the dielectric layer and the like.

In a layered (multilayer) ceramic capacitor, dielectric layers and internal electrodes are stacked alternately. Of the internal electrodes, those placed opposite to each other via the dielectric layer are connected through the via electrode. The layered (multilayer) ceramic capacitor is produced by forming a via hole in stacked layers of a ceramic green sheet for forming the dielectric layer and a conductive paste for forming the internal electrode, followed by firing to obtain stacked layers having the dielectric layers and the internal electrodes formed therein. A conductive paste for forming the via electrode is filled in the via hole of the stacked layers and then baked to form the via electrode.

### BACKGROUND OF THE INVENTION

1. Field of the Invention

The present invention relates to a layered (multilayer) ceramic electronic component and a manufacturing method therefore (a method for producing the same).

2. Description of the Related Art

With a recent demand for further downsizing, thinning, and high-density packaging of electronic devices, there is also an eager demand for reducing the size or thickness of a circuit substrate to be used in electronic devices, which circuit substrate has thereon electronic components including active components, e.g., semiconductor devices such as IC chips and passive components, e.g., capacitors, inductors, thermistors, and resistors.

Of these electronic components, particularly ceramic chip capacitors which are multilayer (layered, stacked) ceramic electronic components are strongly required to have a further increased capacity in addition to a reduced size or thickness. To satisfy the requirement for high-density packaging, thinning of a dielectric and an internal electrode has been promoted rapidly in ceramic chip capacitors because a mounting area of electronic components cannot be increased. At present, even in a C2012 size (external size of 2.0 mm×1.2 mm×1.2 mm), electronic components composed of 800 or more layers are put on the market. In order to cope with a recent tendency to reduce the region of a circuit substrate on which electronic components are mounted, for example, a surface mount type multilayer ceramic capacitor is developed which has, on the upper wall surface and bottom wall surface thereof, an external connection pad or terminal to allow external connection from both sides in a stacking direction without connecting an external electrode to the side surfaces of the capacitor.

As such a type of multilayer ceramic electronic components, Japanese Patent Application Laid-Open No. 2005-136231 proposes a multilayer ceramic electronic component (capacitor) having a plurality of dielectric layers stacked one after another, internal electrodes each made of a sintered product of Ni-particle-containing conductive material and formed between the dielectric layers, and a via conductor made of a sintered product of a conductive material containing Ni particles and Cu particles and arranged to connect the internal electrodes therewith. Japanese Patent Application Laid-Open No. 2003-151851 describes a multilayer ceramic electronic component having a similar constitution, more specifically, the constitution obtained by alternately stacking dielectric ceramic layers and internal wiring patterns one after another and connecting these separated wiring patterns, which are opposite to each other via the dielectric ceramic layers, with a via electrode penetrating through the dielectric ceramic layers.

Japanese Patent Application Laid-Open Nos. 2005-136231 and 2003-151851 describe production methods of the above conventional multilayer ceramic electronic components having internal electrodes which are placed between dielectric layers obtained by sintering and are connected to each other through a via electrode. According to the documents, the multilayer ceramic electronic components are produced by alternately stacking a plurality of dielectric-layer forming ceramic green sheets and internal-electrode forming conductive material layers to obtain stacked layers, forming a via-electrode (via-conductor) forming via hole (through-hole) in the stacked layers, filling (via-filling) the via-hole with a via-electrode forming conductive paste (refer to [0029] of Japanese Patent Application Laid-Open No. 2005-136231 and FIG. 17 of Japanese Patent Application Laid-Open No. 2003-151851) or forming a via hole whenever the ceramic green sheets and the conductive material layers are stacked, filling the via hole with the via-electrode forming conductive paste, and repeating this step to form stacked layers (single system; refer to FIG. 1 of Japanese Patent Application Laid-Open No. 2003-151851); and then firing the whole stacked layers simultaneously.

Detailed investigation of such production methods by the present inventors has however revealed that when a Cu-containing conductive material is used for the formation of a via electrode, the temperature (1100° C. or higher in the case of, for example, a BaTiO₃ ceramic) required for firing the ceramic green sheet is higher than the melting point (1083° C.) of Cu so that Cu in the conductive material in the via hole melts during firing, leading to a failure in the formation of the via electrode. It has also been confirmed that even if the via-electrode forming conductive material contains, in addition to Cu, another material such as Ni (melting point: 1453° C.) having a melting point higher than the firing temperature, melting of Ni is induced by melting of Cu, leading to a failure in the formation of a via electrode conductor. Neither Japanese Patent Application Laid-Open No. 2005-136231 nor Japanese Patent Application Laid-Open No. 2003-151851 describes examples showing a success of actual production of a multilayer ceramic electronic component having a via electrode formed therein by using a Cu-containing conductive material for the formation of a via-electrode in accordance with the above method employing simultaneous firing.

Since the ceramic green sheets and the conductive materials for the formation of the internal electrodes and the via electrode are fired simultaneously, the firing temperature becomes high enough to sinter the ceramic green sheets as described above. At such a high temperature, however, since the ceramic green sheets and the conductive material layers differ in a thermal expansion coefficient, a difference caused by expansion or shrinkage during the firing procedure increases greatly and a gap tends to be created between dielectric layers and a via electrode which are formed by firing. This makes it difficult to provide reliable conduction (electrical connection) between the via electrode and internal electrodes. Moreover, the ceramic green sheets and the conductive material layers usually become relatively fragile as a result of removal of the binder at a relatively low temperature before firing. Simultaneous firing with the conductive layers for forming the internal electrodes and the via electrodes at high temperatures under such a state increases a relative difference in elongation/shrinkage behavior between the ceramic green sheets and the conductive materials, which may lead to an inconvenience, that is, tendency to cause structural defects such as cracks in the dielectric layers and delamination between layers. In particular, such a phenomenon is easily presumed to become apparent in a recent trend toward thinning of layers.

Generally speaking, as a result of detailed study on the above conventional multilayer ceramic electronic components, for example, multilayer ceramic capacitors, the present inventors have found that they may cause some inconveniences. For example, sufficient conduction cannot always be provided between the internal electrodes and via electrode or cracks are liable to be formed in the dielectric layers. The multilayer ceramic capacitor having such an inconvenience cannot exhibit its intended performances fully.

With the forgoing in view, the present invention has been made. An object of the present invention is to provide a multilayer ceramic electronic component and a manufacturing method therefore (production method thereof) capable of providing reliable conduction between a via electrode and an internal electrode while preventing appearance of a gap therebetween, capable of effectively preventing occurrence of structural defects such as cracks in a dielectric layer and the like, and therefore capable of reliably achieving excellent performances, and at the same time, capable of producing such a product in a high yield.

### SUMMARY OF THE INVENTION

With a view to overcoming the above problem, there is provided in the present invention a manufacturing (production) method of a layered (multilayer) ceramic electronic component, which comprises stacking at least one ceramic layer containing a dielectric-layer forming ceramic material and at least one conductive layer containing an internal-electrode forming conductive material to form stacked layers, forming a via hole penetrating through the at least one of the ceramic layers and the at least one of the conductive layers; firing the stacked layers having the via holed formed therein to obtain stacked layers having the dielectric layer and the internal electrode; filling a via-electrode forming conductive material in the via hole of the stacked layers having the dielectric layer and the internal electrode formed therein; and baking the stacked layers having the via hole filled with the conductive material to form a via electrode.

In the manufacturing method of the layered (multilayer) ceramic electronic component having such a constitution, firing treatment is performed after a via hole is made in stacked layers obtained by stacking a dielectric-layer forming green sheet layer and an internal-electrode green sheet layer containing an internal-electrode forming conductive material, in other words, before filling the via hole with a via-electrode forming conductive material. The firing treatment preferably includes, for example, removing a binder from the ceramic layer if necessary, firing at a firing temperature required to sinter the ceramic layer in a reducing atmosphere for the purpose of preventing oxidation of the internal electrodes for which Ni or Ni alloy is used, and carrying out re-oxidation treatment for re-oxidizing the dielectric body if necessary.

Next, a via-electrode forming conductive material is filled in the via hole of the resulting sintered body, followed by baking (in other words, firing again) to obtain a layered (multilayer) ceramic electronic component having a via electrode formed as a result of baking the conductive material in the via hole. Since the ceramic layer has already been fired into a sintered dielectric layer, it is possible to reduce the baking temperature to a sufficiently low level, that is, not greater than the melting point of the conductive material compared with the firing temperature of the ceramic layer and therefore suppress the expansion or contraction degree of the dielectric layer to a sufficiently low level. Accordingly, even if the via-electrode forming conductive material is baked under such a state, a decrease in a relative difference of expansion/contraction (expansion/contraction behavior) between the dielectric layers and the internal electrodes and via electrode can effectively prevent separation and formation of a gap between the dielectric layers and the internal electrodes and via electrode.

Thus, the via-electrode forming conductive material can be baked at a temperature sufficiently lower than the firing temperature of the ceramic layer. This enables to reduce a relative expansion/contraction behavior between the conductive materials for forming the internal electrodes and via electrode and the dielectric layer forming ceramic layers which may otherwise occur in the conventional simultaneous firing treatment, resulting in significant reduction of structural defects such as cracks in the dielectric layers or interlayer delamination.

More specifically, the present invention is particularly useful when using, as the internal-electrode forming conductive material, that containing first metal particles having a melting point higher than the firing temperature of a ceramic material necessary for the formation of the dielectric layers; and as the via-electrode forming conductive material, that containing second metal particles having a melting point lower than the firing temperature of the ceramic material necessary for forming the dielectric layers and third metal particles having a melting point higher than that of the second metal.

As described above, the conventional simultaneous firing treatment in which stacked layers are fired after filling a via hole with a via-electrode forming conductive material cannot form an intended via electrode because when the via-electrode forming conductive material contains a metal having a melting point lower than the firing temperature of the ceramic layer, the metal melts during firing. In the present invention, on the other hand, after firing the ceramic layer and the conductive layer containing the internal-electrode forming conductive material, the via-electrode forming conductive material is baked so that the baking temperature can be reduced to the melting point or less of the second metal contained mainly in the conductive material. Thus, elevation of the baking temperature to the firing temperature of the ceramic layer is not required.

Upon baking the via-electrode forming conductive material, due to high reactivity among particles of the same metal contained in the via-electrode forming conductive material, an excessive progress of a solid solution reaction among the particles occurs and a volume occupied by the particles decreases, which may lead to an excessive reduction in a space filling ratio of the via hole with the conductor particles. Then, there may a possibility that via hole is not filled completely with the conductor and sufficient electrical connection between the internal electrode and via electrode in the via hole cannot be attained. On the other hand, when a via-electrode forming conductive material containing, in addition to the second metal, the third metal particles having a melting point higher than the second metal is used, the third metal particles having a relatively high melting point bind to the second metal while being present between the second metal particles and act as if fixing these second metal particles with a pin (pinning action). The metal reaction among the second metal particles is therefore suppressed moderately and an excessive reduction in the space filling ratio with a metal conductor in the via hole which will otherwise occur due to a reduction in the volume occupied by the metal particles can be suppressed. This enables to achieve more reliable conduction between the internal electrodes and via electrode.

Replacement of particles of an inorganic material having a high melting point such as ceramic for the third metal particles is also taken into consideration from the standpoint that they have similarly a high melting point. Such inorganic materials have however only insufficient affinity with metal particles to be reacted. Although they can suppress the metal reaction among metal particles of the same kind, they cannot stay in a reaction site and are discharged from the metal so that they cannot effectively maintain their pinning action. Use of metal particles having a high melting point is preferred because they can effectively keep their pinning action.

Specific examples of the second metal contained mainly in the via-electrode forming conductive material include Cu (melting point: 1083° C.), Ag (melting point: 961° C.), and Au (melting point: 1063° C.). At least one of these metals is usable. Examples of the third metal include Ni (melting point: 1453° C.), Pt (melting point: 1769° C.), and Pd (melting point: 1552° C.). Of these, at least one metal is usable. Use of a via-electrode forming conductive material containing Cu as the second metal and Ni as the third metal is preferred from the viewpoint that it is particularly excellent in the above action and effect and excellent in both electrical properties and economy. The via electrode mainly containing Cu is advantageous because it can reduce ESR.

The constitution of the layered (multilayer) ceramic electronic component available by the manufacturing method of a multilayer ceramic electronic component according to the present invention will next be described.

The layered (multilayer) ceramic electronic component of the present invention has a dielectric layer made of a fired ceramic material, a plurality of internal electrodes made of a conductive material and arranged with intervals inside the dielectric layer, and a via electrode made of a conductive material, penetrating through the dielectric layer, and connected to at least two of the internal electrodes. The internal electrodes each contains a first metal having a melting point higher than the firing temperature of the ceramic material necessary for forming the dielectric layer and a third metal having a melting point higher than that of the second metal. At the same time, a content ratio of the third metal to the second metal is greater than 0 but less than 40 mass %, preferably 2 mass % or greater but not greater than 30 mass %.

More specifically, it is preferred that the second metal is at least one of Cu, Ag, and Au and the third metal is at least one of Ni, Pt, and Pd. Of these, it is more preferred that the second metal is Cu and the third metal is Ni. In this case, it is more preferred that the second metal particles are made of a conductive material having an average particle size at least twice as much as the average particle size of the third metal particles.

It is to be noted that the term “mainly contains a component” or “contains a component as a main component” means that the mass content of the component in the conductive material is greater than the sum of mass contents of the other components; and the term “mainly contains components” or “contains components as main components” means that the mass content of the sum of the components is greater than the sum of the mass contents of the other components. The term “average particle size” of particles means an average of particle sizes determined as arithmetic average of the minimum distance D1 between two parallel tangent lines which touch the outline of a primary particle and the maximum distance D2 between two parallel tangent lines which touch the outline of the primary particle, which can be observed from a scanning electron micrograph of the tissue section.

According to the manufacturing method of the layered (multilayer) ceramic electronic component of the present invention, the layered (multilayer) ceramic electronic component is obtained by firing stacked layers, which have been obtained by stacking a ceramic layer and a conductive layer containing an internal-electrode forming conductive material one after another, with a via hole made therein; filling a via-electrode forming conductive material in the via hole; and then baking. The via-electrode forming conductive material can be baked at a temperature not greater than the melting point of the conductive material sufficiently lower than the firing temperature of the ceramic layer. This enables to minimize the expansion/contraction degree of the dielectric layers, reduce the relative expansion/contraction degree (expansion/contraction behavior) between the dielectric layers and the internal electrodes and via electrode, and therefore effectively prevent appearance of a gap between the dielectric layers and the internal electrodes and via electrode or occurrence of structural defects of the dielectric layers.

According to the layered (multilayer) ceramic electronic component and manufacturing method thereof of the present invention, the internal electrodes each contains the first metal having a melting point higher than the firing temperature of the ceramic material necessary for forming the dielectric layers; the via electrode contains the second metal having a melting point lower than the firing temperature of the ceramic material necessary for forming the dielectric layers and the third metal having a melting point higher than that of the second metal; and a content ratio of the third metal to the second metal is greater than 0 but less than 40 mass %. This enables to ensure reliable conduction between the internal electrodes and the via electrode and at the same time to effectively prevent occurrence of structural defects such as cracks in the dielectric layers.

### BRIEF DESCRIPTION OF THE DRAWINGS

FIG. 1 is a cross-sectional view illustrating the schematic structure of one example of a layered (multilayer) ceramic electronic component available by the manufacturing method of a layered (multilayer) ceramic electronic component according to the present invention;

FIG. 2 is a step view illustrating a part of one example of production procedures of a layered (multilayer) ceramic capacitor 1; and

FIG. 3 is a step view illustrating another part of one example of production procedures of a layered (multilayer) ceramic capacitor 1.

### DESCRIPTION OF THE PREFERRED EMBODIMENTS

The embodiment of the present invention will next be described referring to some drawings. In these drawings, members of a like function will be identified by like reference numerals and overlapping descriptions will be omitted. The positional relationship such as the vertical or horizontal positional relationship is based on the positional relationship shown in the drawings, unless otherwise indicated. The size ratio in the drawings is not limited to the ratio shown in the drawings. The following embodiment is shown for exemplary only and the present invention is not limited thereto. Moreover, the invention can be modified in various ways insofar as it does not depart from the gist of the present invention.

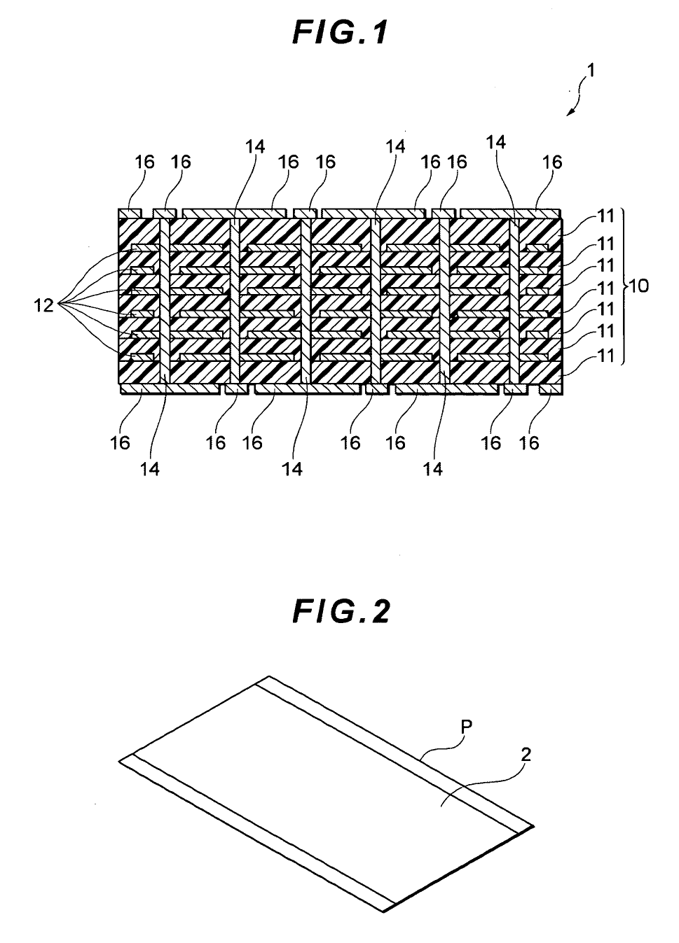

FIG. 1 is a cross-sectional view illustrating the schematic structure of one preferred embodiment of the layered (multilayer) ceramic electronic component available using the manufacturing method of a layered (multilayer) ceramic electronic component according to the present invention. The layered (multilayer) ceramic capacitor 1 illustrated in this drawing is a so-called surface-mount type multilayer ceramic capacitor. In the capacitor, a plurality of patterns of dielectric layers 11 and a plurality of patterns of internal electrodes 12 are stacked alternately. Of the internal electrodes 12, alternate ones arranged opposite to each other with the dielectric layer 11 interposed therebetween are connected to each other with a via electrode 14 placed so as to penetrate the dielectric layers in the stacking direction. An external connection pad 16 is connected to the both ends of each of the via electrodes 14. The external connection pad 16 may have thereon a bump or the like as needed.

In this drawing, the dielectric layers 11 are illustrated as separate layers. As described later, they are formed by firing a stack of a plurality of ceramic green sheets 2, each a precursor layer of the dielectric layer 11, in the production procedure. By firing, they are sintered into one dielectric layer 10 as a whole.

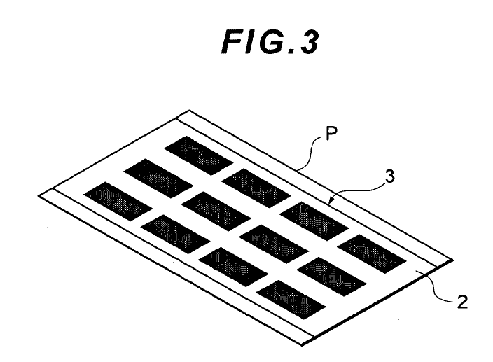

One example of the manufacturing method of the layered (multilayer) ceramic capacitor 1 according to the above embodiment will next be described. FIGS. 2 and 3 are step views illustrating a part of one example of production procedures of the layered (multilayer) ceramic capacitor 1.

First, ceramic powders containing barium titanate (BaTiO₃) ceramic for the formation of the dielectric layers 11 are prepared. The dielectric layers 11 contain barium titanate as a main component and they further contain subsidiary components such as sintering aid component. More specifically, they contain barium titanate as the main component and at least one selected from magnesium oxide, yttrium oxide, dysprosium oxide, and holmium oxide as the subsidiary component. They may also contain as another subsidiary component at least one selected from barium oxide, strontium oxide, and calcium oxide; at least one selected from silicon oxide, manganese oxide, and chromium oxide, and at least one selected from vanadium oxide, molybdenum oxide, and tungsten oxide.

The ceramic powders for the formation of the dielectric layers 11 having such a composition can be prepared, for example, in the following manner. After addition of (MgCO₃)₄/Mg(OH)₂/5H₂O, MnCO₃, BaCO₃, CaCO₃, SiO₂, Y₂O₃, and V₂O₅ to Ba_{1.005}TiO₃ prepared by the hydrothermal synthesis method, the resulting mixture is wet-mixed in a ball mill for about ten and several hours to obtain, as a final composition, raw material powders containing, in Ba_{1.005}TiO₃, MgO, MnO, Y₂O₃, (Ba_{0.6}, Ca_{0.4})SiO₃, and V₂O₅. Examples include a composition containing, in Ba_{1.005}TiO₃, 0.5 mol % of MgO, 0.4 mol % of MnO, 1.0 mol % of Y₂O₃, 1.0 mol % of (Ba_{0.6}, Ca_{0.4})SiO₃, and 0.05 mol % of V₂O₅.

Then, the raw material powders thus obtained are mixed with an organic solvent and an organic binder, and if necessary, plasticizer, antistatic, dispersant, defoaming agent, surfactant, wetting agent and another additive. The ceramic slurry thus obtained is molded or formed in accordance with the doctor blade method, nozzle coater, or the like into a sheet-like ceramic green sheet 2 on a base material P made of a resin film such as polyethylene terephthalate (PET) as illustrated in FIG. 2.

The organic solvent is not particularly limited. Examples include ethanol, butanol, propanol, acetone, diacetone, methyl ethyl ketone, methyl isobutyl ketone, benzene, bromochloromethane, toluene, and xylene. The organic binder is also not particularly limited. Examples include polyvinyl butyral binders, polyvinyl alcohol binders, polyethylene binders, ethyl cellulose binders, acrylic binders, and acrylonitrile binders. Of these, polyvinylbutyral binders are more preferred. Examples of the plasticizer include phthalates esters, derivatives thereof, and polyethylene glycol derivatives.

Then, as illustrated in FIG. 3, patterns for forming internal electrodes 12 as illustrated in FIG. 1 are formed by screen-printing a conductive paste mainly containing a high melting point metal (first metal) on a plurality of separated piece regions 33 for forming the layered (multilayer) ceramic capacitor 1 which are on the ceramic green sheet 2. The conductive paste can be prepared by mixing conductive powders containing metal particles having a melting point higher than the firing temperature of the ceramic green sheet 2 which will be described later, such as Ni, Pt, or Pd, or alloy powders or composite metal having such a metal as a main component, with a common material, organic binder, and organic solvent and if necessary, plasticizer, dispersant, defoaming agent, additive, or the like. As the common material, ceramic of the same kind as that contained in the ceramic green sheet 2 is preferred. It may contain an additive as needed. The organic binder is not particularly limited and examples of it include ethyl cellulose binders, polyvinyl butyral binders, and acrylonitrile binders. Of these, ethyl cellulose ones are more preferred.

Then, the ceramic green sheet 2 having thereon patterns for forming the internal electrodes 12 corresponding to a plurality of separated pieces and the ceramic green sheet 2 having no pattern formed thereon are stacked alternately one after another by an appropriate method to obtain a stacked layers structure (the structure of FIG. 1 in which neither via electrode 14 nor external connection pad 16 has been formed) in which a plurality of substrate structures of the layered (multilayer) ceramic capacitor 1 illustrated in FIG. 1 have been formed. Examples of the stacking method include a method of forming, on the ceramic green sheet 2 illustrated in FIG. 3, the ceramic green sheet 2 illustrated in FIG. 2 with a nozzle coater by using the doctor blade method and then printing patterns for forming the internal electrodes 12 corresponding to a plurality of separated pieces illustrated in FIG. 3; and a method of stacking the ceramic green sheet 2 illustrated in FIG. 3 from which the base material P such as PET film has been released on the ceramic green sheet illustrated in FIG. 3 one after another. Alternately, they may be stacked prior to release of the base material P, followed by release of the base material P from one or both of the sheets. On the other hand, whenever stacking, they may be pressure bonded by applying heat or pressure thereto.

Next, the stacked layers structures are pressure bonded (green pressed) further by using, either singly or in combination, pressing methods such as mold pressing, (standard temperature) isostatic pressing (SIP), and warm isostatic pressing (WIP). A via hole (through holes) is then made at a position of the pressure-bonded layered structures where the via electrode 14 is to be placed. The via hole is made, for example, by using a micro-drill, a mechanical punch, or a laser ablation system. Of these, use of a micro-drill is preferred because of the following reason. Described specifically, the mechanical punch does not have an enough punch strength when the stacked layers structure has a certain thickness and it may cause a phenomenon such as bending of the stacked layers structure or the punch itself. When via holes are formed simultaneously by using laser, on the other hand, the diameter of the holes may become smaller than the hole size on the surface (beam diameter of the laser) of the stacked layers structure with an increase in the depth of the stacked layers structure. This makes a hole formation cost higher than that using the micro-drill. Use of the micro-drill not causing such inconveniences is therefore preferred.

Then, the stacked layers structure having a via hole formed therein are cut and divided. No particular limitation is imposed on the cutting method and, for example, dicing with a dicer may be employed. The stacked layers structure is divided into separated pieces. These respective pieces are subjected to binder removal treatment, for example, in a H₂/N₂ reducing atmosphere, an inert gas atmosphere, or atmosphere of several hundred ° C., followed by firing for a predetermined time in a reducing atmosphere (for example, a H₂/N₂ atmosphere having an oxygen partial pressure less than 1.0×10⁻² Pa) of from about 1100 to 1400° C. Then, the fired product is re-oxidized (annealed) for a predetermined time in an atmosphere (N₂ atmosphere) having an oxygen partial pressure of 1.0×10⁻⁸ Pa or greater which is higher than that of the above reducing atmosphere, at from 900 to 1200° C. As a result, the sintered structure in which the ceramic green sheet 2 has been sintered with a via-hole opened therein is prepared.

A conductive paste for forming a via electrode 14 is filled in the via hole of the sintered structure of each piece. The conductive paste can be prepared, for example, by mixing an organic binder with conductive powders mainly containing particles of a second metal, that is, at least one metal selected from Cu, Ag, and Au or an alloy or composite metal containing the above metal as a main component and further containing particles of a third metal, that is, at least one metal selected from Ni, Pt, and Pd or an alloy or composite metal containing the above metal as a main component. The conductive powders are more preferred when they mainly contain Cu powders (including alloy powders or composite metal powders mainly containing Cu, which will equally apply hereinafter) and are mixed with Ni powders (including alloy powders or composite metal powders mainly containing Ni, which will equally apply hereinafter). No particular limitation is imposed on the kind of the organic binder and examples include ethyl cellulose, polyvinyl butyral, and acrylonitrile binders. Of these, ethyl cellulose binders are more preferred. The conductive paste may contain glass frit as an aid from the viewpoint of improving the adhesion between the dielectric layer 11 and the via electrode 14.

No particular limitation is imposed on the shape of the Cu particles or Ni particles contained in the conductive powders and they may be spherical, square, or flat. Of these, the spherical shape is preferred. Their particle size and particle size distribution are also not particularly limited and those having an average particle size of from submicron order to several ten micron order can be used.

A description will next be made of an example in which conductive powders obtained by mixing Cu powders with Ni powders are used. In the mixed conductive powders, a content ratio of Ni to Cu is preferably greater than 0 but less than 40 mass %, more preferably from 2 mass % to 30 mass %. When the content ratio is great than 0, meaning that even a slight amount of Ni powders is contained in Cu powders, it becomes possible, in the layered (multilayer) ceramic capacitor 1 as a final product, to completely fill the via hole with the via electrode 14 and ensure reliable conduction between the internal electrodes 12 and the via electrode 14, and at the same time, prevent occurrence of structural defects such as cracks and moreover, improve the humidity resistance. On the other hand, content ratios less than 40 mass % enable to improve the conduction performance between the internal electrodes 12 and the via electrode 14 further and moreover, to prevent occurrence of structural defects steadily. Contents of 2 mass % or greater but not greater than 30 mass % are more useful because the layered (multilayer) ceramic capacitor 1 having such a content ratio can have further improved humidity resistance.

A description will next be described using also conductive powders containing both Cu powders and Ni powders as an example. When the average particle size of the Cu particles becomes at least twice as much as that of the Ni particles, the resulting conductive powders can easily prevent occurrence of delamination of the layered (multilayer) ceramic capacitor 1. Use of such conductive powders is therefore preferred. Combination of Ni as a main component of the conductive material of the internal electrode 12 and Cu as a main component of the conductive material of the via electrode 14 is preferred because it raises the activity of an alloy reaction between Ni and Cu (high reaction), binds them firmly, and facilitates reliable conduction. On the other hand, for example, combination of Ni as a main component of conductive material of the internal electrode 12 and also Ni as a main component of the conductive material of the via electrode 14 tends to fail in ensuring reliable conduction between the internal electrode 12 and the via electrode 14, because a reaction between the Ni of the internal electrode 12 and Ni in the conductive material of the via electrode 14 after baking is relatively low.

No particular limitation is imposed on the method of filling the conductive paste in the via hole of the sintered structure insofar as it can fill the conductive paste completely. Examples include pressure printing, printing by hand, vacuum suction, and forcing with a squeegee.

Then, the sintered structure having the via hole filled with the conductive paste is subjected to binder-removal treatment, for example, in a H₂/N₂ reducing atmosphere, an inert gas atmosphere or atmosphere of several hundred ° C., followed by baking treatment for a predetermined time in an atmosphere of from about 700 to 900° C., for example, a H₂/N₂ reducing atmosphere or an atmosphere containing a N₂ gas as a main component and having an oxygen partial pressure controlled with at least one of H₂, H₂O, CO₂ and CO gases. As a result, a structure having the via electrode 14 formed therein (the layered (multilayer) ceramic capacitor 1 illustrated in FIG. 1 in which the external connection pad 16 has not yet been formed) is obtained.

A conductive paste containing a proper conductor is applied onto both end portions of the via electrode 14 on the upper wall surface and bottom wall surface of the structure to form patterns of an external connection pad. They are then fired at a predetermined temperature for a predetermined time in a proper atmosphere to form the external connection pads 16. In such a manner, the layered (multilayer) ceramic capacitor 1 as illustrated in FIG. 1 is obtained.

According to the aforementioned layered (multilayer) ceramic capacitor 1 and the manufacturing method of the present invention, after forming the via hole in the stacked layers structure of the ceramic green sheet 2 and the pattern of the conductive paste for forming the internal electrode 12 and then firing the resulting structure, the conductive paste for forming the via electrode 14 is filled in the via hole, followed by baking treatment. This means that when the conductive paste for forming the via electrode 14 is subjected to baking treatment, the dielectric layers 11 (integrated into the dielectric layer 10) which are the sintered ceramic green sheets 2 have already been formed so that the baking temperature can be made not greater than the melting point of the conductive material sufficiently lower than the firing temperature of the ceramic green sheet 2. This enables to minimize the expansion/contraction degree of the dielectric layers 11.

Even if baking of the conductive paste for forming the via electrode 14 is performed under such a state, a relative difference in the expansion/contraction degree between the dielectric layers 11 and the internal electrodes 12 and via electrode 14 can be reduced, resulting in effective prevention of separation and appearance of a gap between the dielectric layers 11 and the internal electrodes 12 and via electrode 14. This enables to ensure reliable conduction between the via electrode 14 and the internal electrode 12. In addition, since the appearance of a gap in the via hole is prevented and the via hole is filled completely with the via electrode 14, a product having improved humidity resistance and causing less time-dependent deterioration can be obtained.

In addition, since the dielectric layers 11 and the internal electrodes 12 are formed by firing prior to baking the conductive paste for forming the via electrode 14, the conductive paste can be baked at an adequately low temperature compared with the firing temperature of the ceramic green sheet 2 and a difference in a expansion/contraction behavior between the conductive pastes for forming the internal electrodes 12 and for forming the via electrode 14 and the ceramic green sheet 2 can be reduced. As a result, it becomes possible to suppress occurrence of the structural defects such as cracks in the dielectric layers 11 and delamination.

When the mixed conductive powders containing, in addition to metal powders such as Cu, metal powders such as Ni having a higher melting point are used as the conductive paste for forming the via electrode 14, the high-melting-point Ni powders are bonded to the low-melting-point Cu powders with the Ni powders interposed between the Cu powders and therefore have a pinning effect to the Cu particles so that advance of a metal reaction between metals such as Cu can be suppressed adequately. This enables to effectively prevent an excessive reduction in the space filling ratio of the via hole with Cu or the like, which will otherwise occur due to an excessive progress of a reaction between metals such as Cu to reduce the volume occupied thereby. As a result, more reliable conduction between the internal electrode and the via electrode 14 can be achieved.

The layered (multilayer) ceramic capacitor 1 having excellent performances can therefore be produced efficiently in a high yield so that both productivity and economy can also be improved.

In addition, since the conductive paste for forming the via electrode 14 contains the mixed conductive powders obtained by adding Ni powders to Cu powders and a content ratio of Ni to Cu in the resulting mixed conductive powders is greater than 0 but less than 40 mass %, the via hole is filled completely with the via electrode 14 in the final product of the layered (multilayer) ceramic capacitor 1 and reliable conduction between the internal electrode 12 and the via electrode 13 can be achieved. In addition, occurrence of structural defects such as cracks can be prevented and moreover, humidity resistance can be improved. When the content ratio is 2 mass % or greater but not greater than 30 mass %, the resulting layered (multilayer) ceramic capacitor 1 can have further improved humidity resistance.

As described above, the present invention is not limited to or by the above embodiment and can be changed s needed without departing from the gist of the invention. For example, the layered (multilayer) ceramic electronic component and the manufacturing method thereof according to the present invention can be applied, in addition to the examples shown in the above embodiment, to not only a layered (multilayer) ceramic capacitor and a manufacturing method thereof but also another layered (multilayer) ceramic electronic component such as layered (multilayer) ceramic inductor and manufacturing method thereof.

### EXAMPLES

Examples of the present invention will hereinafter be described. It should however be borne in mind that the invention is not limited to or by these examples.

### (Production of Layered (Multilayer) Ceramic Capacitor)

In a similar manner to the production procedures as described above, a layered (multilayer) ceramic capacitor having a similar structure to that illustrated in FIG. 1 was produced. The following are specific principal processing conditions. Described specifically, the thickness of a ceramic green sheet after drying was adjusted to approximately 5 μm. The thickness of a pattern of a conductive paste for internal electrode formation formed on the ceramic green sheet was adjusted to approximately 1.2 μm. A via hole formed in the stacked layers structure was made using a microdrill (drill diameter: 150 μm, rotation speed: 100000 rpm). Division into each separated piece was effected using a dicer having a cutting blade having a thickness of 0.35 mm. Removal of the binder from the stacked layers structure having a via hole formed therein was carried out in a H₂/N₂ reducing atmosphere of 400° C. Firing after the removal was performed for 2 hours in a strong H₂/N₂ reducing atmosphere of from 1150 to 1300° C. Filling of a via-electrode forming conductive paste in the via hole was achieved by repeating vacuum suction printing five times.

An internal electrode was formed using a conductive paste containing Ni powders as a main component. On the other hand, a via electrode was formed by using a conductive paste containing mixed conductive powders obtained by adding Ni powders to Cu powders contained as a main component. A plurality of layered (multilayer) ceramic capacitors was produced by changing the average particle size of Cu particles and the average particle size of Ni particles contained in the via-electrode forming conductive paste, and a Ni/Cu content ratio (mass %) in the mixed conductive powders.

### (Evaluation 1)

Various layered (multilayer) ceramic capacitors thus obtained were evaluated for (1) conductivity, (2) crack occurrence, (3) delamination occurrence, and (4) failure occurrence in humidity resistance test.

In the evaluation of conductivity (1), a ratio (percentage: %) of an actual capacity measured to a desired capacity (design specification) of a layered (multilayer) ceramic capacitor is used as an index. Although the presence or absence of conduction can be confirmed also by the current-resistance measurement, a reading sensitivity in the measurement of capacity is superior to that in the measurement of resistance, enabling more accurate evaluation so that the evaluation is performed using the measurement of the capacity.

In the evaluation of crack occurrence (2), six planes, that is, flat surfaces, side surfaces, and end surfaces of the layered (multilayer) ceramic capacitor thus obtained are observed with a stereoscopic microscope by enlarging to 10 times and the number of dielectric layers in which cracks have occurred is counted. A ratio (percentage: %) of the number of capacitors in which cracks have occurred to the number of capacitor samples provided for the observation is calculated and used as an index.

In the evaluation of delamination occurrence (3), the side surfaces of a plurality of samples of the layered (multilayer) ceramic capacitors produced under the same conditions are polished so as to expose the entire cross-section of the via. From the microscopic observation of the cross-section of the samples, the number of samples in which interlayer delamination has occurred is counted and a ratio (percentage: %) of the number of the samples in which delamination has occurred to the number of the samples provided for the observation is calculated and used as an index.

In the evaluation of failure occurrence in moisture resistance test (4), when by the application of a voltage twice as much as a rated voltage to the layered (multilayer) ceramic capacitor for 3 hours under the environment of 121° C. and 95% humidity, a leakage current becomes greater by a degree of magnitude than the leakage current at the starting time of the test, the sample is regarded as a failure and the number of it is counted. A ratio (percentage: %) of the number of failures to the number of the samples provided for the observation is calculated and provided as an index.

Both various production conditions and various evaluation results are shown in Table 1.

TABLE 1

| | | | | Evaluation results of characteristics of layered | | | |
|---|---|---|---|---|---|---|---|
| Conductive paste for forming via electrode | | | | (multilayer) ceramic capacitor | | | |
| Average particle size of | Average particle | Ni/Cu | Cu/Ni average particle | | Crack | Delamination | Failure occurrence in |
| Cu particles | size of Ni particles | content | size ratio | Conductivity | occurrence | occurrence | humidity resistance |
| (μm) | (μm) | ratio (%) | (times) | (%) | (%) | (%) | test (%) |
| 20 | — | 0 | — | 93 | 0 | 0 | 1 |
| | 0.2 | 2 | 100 | 100 | 0 | 0 | 0 |
| | | 5 | | 100 | 0 | 0 | 0 |
| | | 10 | | 100 | 0 | 0 | 0 |
| | | 20 | | 100 | 0 | 0 | 1 |
| | | 30 | | 100 | 0 | 0 | 1 |
| | | 40 | | 94 | 2 | 0 | 2 |
| 20 | 0.4 | 2 | 50 | 100 | 0 | 0 | 0 |
| | | 5 | | 100 | 0 | 0 | 0 |
| | | 10 | | 100 | 0 | 0 | 0 |
| | | 20 | | 100 | 0 | 0 | 1 |
| | | 30 | | 99 | 0 | 0 | 2 |
| | | 40 | | 94 | 2 | 0 | 3 |
| 20 | 1 | 2 | 20 | 100 | 0 | 0 | 0 |
| | | 5 | | 100 | 0 | 0 | 0 |
| | | 10 | | 100 | 0 | 0 | 0 |
| | | 20 | | 100 | 0 | 0 | 1 |
| | | 30 | | 99 | 0 | 0 | 2 |
| | | 40 | | 94 | 2 | 0 | 3 |
| 20 | 10 | 2 | 2 | 100 | 0 | 0 | 0 |
| | | 5 | | 100 | 0 | 0 | 0 |
| | | 10 | | 100 | 0 | 0 | 0 |
| | | 20 | | 99 | 0 | 0 | 1 |
| | | 30 | | 99 | 0 | 0 | 3 |
| | | 40 | | 93 | 1 | 1 | 4 |
| 20 | 20 | 2 | 1 | 100 | 0 | 1 | 0 |
| | | 5 | | 100 | 0 | 2 | 1 |
| | | 10 | | 100 | 0 | 4 | 3 |
| | | 20 | | 99 | 0 | 4 | 4 |
| | | 30 | | 97 | 0 | 5 | 4 |
| | | 40 | | 89 | 1 | 8 | 5 |
| 0.5 | 0.025 | 5 | 20 | 100 | 0 | 0 | 0 |
| 1 | 0.05 | | | 100 | 0 | 0 | 0 |
| 2 | 0.1 | | | 100 | 0 | 0 | 0 |
| 5 | 0.25 | | | 100 | 0 | 0 | 0 |
| 10 | 0.5 | | | 100 | 0 | 0 | 0 |
| 20 | 1 | | | 100 | 0 | 0 | 0 |
| 25 | 1.25 | | | 100 | 0 | 0 | 0 |
| 30 | 1.5 | | | 100 | 0 | 0 | 0 |
| 40 | 2 | | | 100 | 0 | 0 | 0 |
| 50 | 2.5 | | | 100 | 0 | 0 | 0 |

It has been confirmed by the results shown in Table 1 that the manufacturing method of a layered (multilayer) ceramic electronic component according to the present invention can provide a sufficiently high conductivity, can reduce the occurrence of structural defects such as cracks and delamination, and moreover can sufficiently suppress a failure occurrence in the humidity resistance test.

Both various production conditions and various evaluation results are shown collectively in Table 2. It includes, as Comparative Examples, an example of Table 1 in which the conductive paste does not contain Ni particles and a test in which the conductive paste contains not Cu particles but Ni particles.

TABLE 2

| | | | | | Evaluation results of characteristics of layered | | | |
|---|---|---|---|---|---|---|---|---|
| | Conductive paste for forming via electrode | | | | (multilayer) ceramic capacitor | | | |
| | Average particle | Average particle | Ni/Cu | Cu/Ni average | | Crack | Delamination | Failure occurrence in |
| | size of Cu | size of Ni | content | particle size ratio | Conductivity | occurrence | occurrence | humidity resistance |
| | particles (μm) | particles (μm) | ratio (%) | (times) | (%) | (%) | (%) | test (%) |
| Comp. Ex. | — | 0.4 | — | — | 30 | 45 | 85 | 42 |
| | 20 | — | 0 | — | 93 | 0 | 0 | 1 |
| Examples | 20 | 0.2 | 2 | 100 | 100 | 0 | 0 | 0 |
| | | | 5 | | 100 | 0 | 0 | 0 |
| | | | 10 | | 100 | 0 | 0 | 0 |
| | | | 20 | | 100 | 0 | 0 | 1 |
| | | | 30 | | 100 | 0 | 0 | 1 |
| | | | 40 | | 94 | 2 | 0 | 2 |
| | 20 | 0.4 | 2 | 50 | 100 | 0 | 0 | 0 |
| | | | 5 | | 100 | 0 | 0 | 0 |
| | | | 10 | | 100 | 0 | 0 | 0 |
| | | | 20 | | 100 | 0 | 0 | 1 |
| | | | 30 | | 99 | 0 | 0 | 2 |
| | | | 40 | | 94 | 2 | 0 | 3 |
| | 20 | 1 | 2 | 20 | 100 | 0 | 0 | 0 |
| | | | 5 | | 100 | 0 | 0 | 0 |
| | | | 10 | | 100 | 0 | 0 | 0 |
| | | | 20 | | 100 | 0 | 0 | 1 |
| | | | 30 | | 99 | 0 | 0 | 2 |
| | | | 40 | | 94 | 2 | 0 | 3 |
| | 20 | 10 | 2 | 2 | 100 | 0 | 0 | 0 |
| | | | 5 | | 100 | 0 | 0 | 0 |
| | | | 10 | | 100 | 0 | 0 | 0 |
| | | | 20 | | 99 | 0 | 0 | 1 |
| | | | 30 | | 99 | 0 | 0 | 3 |
| | | | 40 | | 93 | 1 | 1 | 4 |
| | 20 | 20 | 2 | 1 | 100 | 0 | 1 | 0 |
| | | | 5 | | 100 | 0 | 2 | 1 |
| | | | 10 | | 100 | 0 | 4 | 3 |
| | | | 20 | | 99 | 0 | 4 | 4 |
| | | | 30 | | 97 | 0 | 5 | 4 |
| | | | 40 | | 89 | 1 | 8 | 5 |
| | 0.5 | 0.025 | 5 | 20 | 100 | 0 | 0 | 0 |
| | 1 | 0.05 | | | 100 | 0 | 0 | 0 |
| | 2 | 0.1 | | | 100 | 0 | 0 | 0 |
| | 5 | 0.25 | | | 100 | 0 | 0 | 0 |
| | 10 | 0.5 | | | 100 | 0 | 0 | 0 |
| | 20 | 1 | | | 100 | 0 | 0 | 0 |
| | 25 | 1.25 | | | 100 | 0 | 0 | 0 |
| | 30 | 1.5 | | | 100 | 0 | 0 | 0 |
| | 40 | 2 | | | 100 | 0 | 0 | 0 |
| | 50 | 2.5 | | | 100 | 0 | 0 | 0 |

It has been confirmed from the results in Table 2 that the layered (multilayer) ceramic electronic components having an Ni/Cu content ratio, in mixed conductive powders for forming the via electrode, exceeding 0 but less than 40 mass % enable to provide a sufficiently high conductivity, decrease an occurrence of structural defects such as cracks, and suppress a failure occurrence in the humidity resistance test to a sufficiently low level. It has also been confirmed that when the content ratio is 2 mass % or greater but not greater than 30 mass %, the layered (multilayer) ceramic capacitor can have improved humidity resistance. It has been confirmed further that when the average particle size of Cu particles in the mixed conductive powders is at least twice as much as that of the Ni particles, delamination of the layered (multilayer) ceramic capacitor can be prevented further.

### (Evaluation 2)

As a conductive paste for via electrode formation, mixed conductive powders containing Cu particles having an average particle size of 20 μm and Ni particles having an average particle size of 1 μm at a Ni/Cu content ratio of 10 mass % was used. The side surfaces of the sample of the layered (multilayer) ceramic capacitor were polished to expose the entire via cross-section. After polishing with a sand paper of about No. 1000, mirror-finish treatment (rough finish with 1 μm followed by main finish with 0.4 μm) was performed with a 1 μm/0.4 μm diamond paste. The via cross-section was subjected to element mapping using EPMA (Electron-Probe Microanalyzer). As a result, it was confirmed that the Ni particles were combined with the Cu particles while being sandwiched between the Cu particles.

### INDUSTRIAL APPLICABILITY

The present invention can prevent appearance of gaps between the dielectric layer and the via electrode, thereby providing reliable conduction between the via electrode and the internal electrode and at the same time, can effectively prevent occurrence of structural defects in the dielectric layer and the like. This make is possible to produce a layered (multilayer) ceramic electronic component having excellent performances in a high yield so that the manufacturing method of the present invention can be used widely and effectively for the production of layered (multilayer) ceramic electronic components such as layered (multilayer) ceramic capacitor and layered (multilayer) ceramic inductor, and apparatuses, devices, systems, and equipments having such a component; and production of them.

The present application is based on Japanese priority applications No. 2008-208459 filed on August 13, 2008 and No. 2008-208498 filed on August 13, 2008, the entire contents of which are hereby incorporated by reference.

What is claimed is:

1. A method for manufacturing a layered ceramic electronic component, which comprises:
stacking at least one ceramic layer containing a dielectric-layer forming ceramic material and at least one conductive layer containing an internal-electrode forming conductive material to form stacked layers,
forming a via hole penetrating through the at least one ceramic layer and the at least one conductive layer;
firing the stacked layers having the via hole made therein to obtain the stacked layers having a dielectric layer and an internal electrode;
filling a via-electrode forming conductive material in the via hole of the stacked layers having the dielectric layer and the internal electrode formed therein; and
baking the stacked layers having the via hole filled with the conductive material to form a via electrode.

2. The method for manufacturing a layered ceramic electronic component according to claim 1, wherein:
the internal-electrode forming conductive material contains first metal particles having a melting point higher than a baking temperature of the ceramic material necessary for forming the dielectric layer; and
the via-electrode forming conductive material contains second metal particles having a melting point lower than the firing temperature of the ceramic material necessary for forming the dielectric layer and third particles having a melting point higher than the melting point of the second metal.

3. The method for manufacturing a layered ceramic electronic component according to claim 2, wherein:
the second metal is at least one metal selected from Cu, Ag, and Au, and
the third metal is at least one metal selected from Ni, Pt, and Pd.

4. The method for manufacturing a layered ceramic electronic component according to claim 2, wherein:
the second metal is Cu, and
the third metal is Ni.

5. A layered ceramic electronic component comprising:
a dielectric layer composed of a fired ceramic material,
a plurality of internal electrodes composed of a conductive material and separated from each other inside the dielectric layer, and
a via electrode composed of a conductive material, penetrating through the dielectric layer, and connected to at least one of the internal electrodes, wherein:
the internal electrodes contain a first metal having a melting point higher than a firing temperature of the ceramic material necessary for forming the dielectric layer, and
the via electrode contains a second metal having a melting point lower than the firing temperature of the ceramic material necessary for forming the dielectric layer and a third metal having a higher melting point than the melting point of the second metal, while having a content ratio of the third metal to the second metal exceeding 0 but less than 40 mass %.

6. The layered ceramic electronic component according to claim 5, wherein the via electrode has a content ratio of the third metal to the second metal from 2 mass % to 30 mass %.

7. The layered ceramic electronic component according to claim 5, wherein in the via electrode, the second metal particles have an average particle size at least twice as much as the particle size of the third metal particles.

8. The layered ceramic electronic component according to claim 5, wherein:
the second metal is at least one metal selected from Cu, Ag, and Au; and
the third metal is at least one metal selected from Ni, Pt, and Pd.

9. The layered ceramic electronic component according to claim 5, wherein:
the second metal is Cu; and
the third metal is Ni.

10. A method for manufacturing a layered ceramic electronic component, which comprises:
forming a dielectric layer composed of a fired ceramic material,
forming a plurality of internal electrodes composed of a conductive material and separated from each other inside the dielectric layer; and
forming a via electrode composed of a conductive material, penetrating through the dielectric layer, and connected to at least one of the internal electrodes, wherein:
the internal electrodes contain a first metal having a melting point higher than a firing temperature of the ceramic material necessary for forming the dielectric layer; and
the via electrode contains second metal particles having a melting point lower than the firing temperature of the ceramic material necessary for forming the dielectric layer and third metal particles having a melting point higher than the melting point of the second metal, while having a content ratio of the third metal to the second metal exceeding 0 but less than 40 mass %.
